(19) United States
(12) Patent Application Publication
(10) Pub. No.: US 2025/0081673 A1
(43) Pub. Date: Mar. 6, 2025

(54) DISPLAY DEVICE AND LIGHT EMITTING ELEMENT

(71) Applicant: Samsung Display Co., LTD., Yongin-si (KR)

(72) Inventors: So Young LEE, Yongin-si (KR); Bong Chun PARK, Yongin-si (KR); Kwan Jae LEE, Yongin-si (KR); Dong Eon LEE, Yongin-si (KR); Seung A LEE, Yongin-si (KR); Jong Jin LEE, Yongin-si (KR)

(73) Assignee: Samsung Display Co., LTD., Yongin-si (KR)

(21) Appl. No.: 18/819,017

(22) Filed: Aug. 29, 2024

(30) Foreign Application Priority Data
Sep. 6, 2023 (KR) 10-2023-0118334

(51) Int. Cl. H01L 33/14; H01L 25/16; H01L 33/62

(52) U.S. Cl. CPC H10H 20/816; H01L 25/167; H10H 20/857

(57) ABSTRACT

A display device includes a first electrode and a second electrode spaced apart from each other, and light emitting elements disposed between the first electrode and the second electrode. Each of the light emitting elements include a first semiconductor layer, a second semiconductor layer disposed on the first semiconductor layer, and an active layer disposed between the first semiconductor layer and the second semiconductor layer. Each of the light emitting elements emits light with a wavelength in a range of about 464 nm to about 468 nm at a current density in a range of about 0.5 A/cm² to about 100 A/cm², and has a maximum external quantum efficiency greater than or equal to about 15%.

### CROSS-REFERENCE TO RELATED APPLICATION(S)

This application claims priority to and benefits of Korean patent application No. 10-2023-0118334 under 35 U.S.C. § 119, filed on Sep. 6, 2023, in the Korean Intellectual Property Office (KIPO), the entire contents of which are incorporated herein by reference.

### BACKGROUND

### 1. Technical Field

The disclosure relates to a display device and a light emitting element.

### 2. Description of the Related Art

Recently, as interest in information display is increasing, research and development on display devices are continuously made.

### SUMMARY

The problem to be solved by the disclosure is to improve the reliability of a light emitting element.

The object of the disclosure is not limited to the aforesaid, but other objects not described herein will be clearly understood by those skilled in the art from descriptions below.

A display device according to an embodiment may include a first electrode and a second electrode spaced apart from each other, and light emitting elements disposed between the first electrode and the second electrode. Each of the light emitting elements may include a first semiconductor layer, a second semiconductor layer disposed on the first semiconductor layer, and an active layer disposed between the first semiconductor layer and the second semiconductor layer. Each of the light emitting elements may emit light with a wavelength in a range of about 464 nm to about 468 nm at a current density in a range of about 0.5 A/cm² to about 100 A/cm², and each of the light emitting elements may have a maximum external quantum efficiency greater than or equal to about 15%.

A thickness of the active layer may be in a range of about 1.0 nm to about 2.8 nm.

A mole fraction of indium in the active layer may be in a range of about 0.17 to about 0.20.

A length of the light emitting elements may be less than or equal to about 50 um.

The first electrode may overlap the first semiconductor layer in a plan view, and the second electrode may overlap the second semiconductor layer in a plan view.

The display device may further include a first connection electrode and a second connection electrode disposed on the light emitting elements.

The first connection electrode may be electrically connected to the first semiconductor layer, and the second connection electrode may be electrically connected to the second semiconductor layer.

The first connection electrode may be electrically connected to the first electrode, and the second connection electrode may be electrically connected to the second electrode.

The display device may further include a color conversion layer disposed on the light emitting elements.

The color conversion layer may include a first color conversion layer, a second color conversion layer, and a scattering layer.

The first color conversion layer may include a first quantum dot, and the second color conversion layer may include a second quantum dot.

The scattering layer may include a scattering body.

The display device may further include a color filter layer disposed on the color conversion layer.

The color filter layer may include a first color filter overlapping the first color conversion layer in a plan view, a second color filter overlapping the second color conversion layer in a plan view, and a third color filter overlapping the scattering layer in a plan view.

The display device may further include a light blocking layer disposed between the first color filter, the second color filter, and the third color filter.

A light emitting element according to an embodiment may include a first semiconductor layer, a second semiconductor layer disposed on the first semiconductor layer, and an active layer disposed between the first semiconductor layer and the second semiconductor layer. The light emitting element may emit light with a wavelength in a range of about 464 nm to about 468 nm at a current density in a range of about 0.5 A/cm² to about 100 A/cm², and the light emitting element may have a maximum external quantum efficiency greater than or equal to about 15%.

A thickness of the active layer may be in a range of about 1.0 nm to about 2.8 nm.

A mole fraction of indium in the active layer may be in a range of about 0.17 to about 0.20.

The light emitting element may further include an electrode layer disposed on the first semiconductor layer.

The light emitting element may further include an insulating film surrounding the first semiconductor layer, the active layer, and the second semiconductor layer.

Specific details of other embodiments are included in specification and drawings.

According to an embodiment of the disclosure, the reliability of the light emitting element may be improved by increasing the emission wavelength of the light emitting element.

Effects are not limited by contents exemplified above, and more various effects are included in the specification.

### BRIEF DESCRIPTION OF THE DRAWINGS

FIG. 1 is a perspective view of a light emitting element according to an embodiment.

FIG. 2 is a schematic cross-sectional view of a light emitting element according to an embodiment.

FIG. 3 is a plan view of a display device according to an embodiment.

FIG. 4 is a schematic diagram of an equivalent circuit of a pixel according to an embodiment.

FIGS. 5 and 6 are plan views of pixels according to an embodiment.

FIG. 7 is a schematic cross-sectional view taken along line A-A′ of FIG. 5.

FIG. 8 is a schematic cross-sectional view taken along line B-B′ of FIG. 5.

FIG. 9 is a schematic cross-sectional view taken along line C-C′ of FIG. 6.

FIG. 10 is a schematic cross-sectional view taken along line D-D′ of FIG. 6.

FIG. 11 is a schematic cross-sectional view of first to third pixels according to an embodiment.

FIG. 12 is a schematic cross-sectional view of a pixel according to an embodiment.

### DETAILED DESCRIPTION OF THE EMBODIMENTS

Advantages and features of the disclosure, and implementation methods thereof will be clarified through following embodiments described with reference to the accompanying drawings. However, the disclosure is not limited to the embodiments disclosed below, and may be implemented in various different forms. These embodiments are provided so that the disclosure of the disclosure is complete, and to completely inform the scope of the disclosure those of ordinary skill in the art of the disclosure, and the disclosure will be defined by a scope of claims.

The term used in this specification is for the purpose of describing the embodiments and is not intended to limit the disclosure. In this specification, the singular also includes the plural unless otherwise specified. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

In addition, the term “connection” or “access” may refer to a physical and/or electrical connection or access collectively. In addition, it may refer to a direct or indirect connection or access and an integral or non-integral connection or access collectively.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numerals designate the same elements throughout the specification.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first”, “second”, and the like are used to describe various constituent elements, these constituent elements are not limited by these terms. These terms are used only to distinguish one constituent element from another constituent element. Therefore, the first constituent elements described below may be the second constituent elements within the technical spirit of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, referring to the drawings, we explain the disclosure in detail.

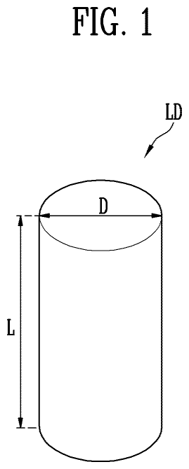

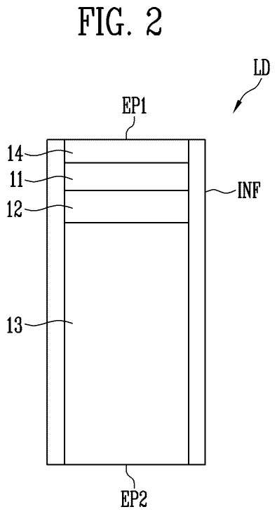

FIG. 1 is a perspective view of a light emitting element according to an embodiment. FIG. 2 is a schematic cross-sectional view of a light emitting element according to an embodiment. FIGS. 1 and 2 illustrate a pillar shape of a light emitting element LD, but the type and/or shape of the light emitting element LD is not limited thereto.

Referring to FIGS. 1 and 2, the light emitting element LD may include a first semiconductor layer 11, an active layer 12, a second semiconductor layer 13, and/or an electrode layer 14.

The light emitting element LD may be formed in a pillar shape extending in a direction. The light emitting element LD may have a first end EP1 and a second end EP2. One of the first and second semiconductor layers 11 and 13 may be disposed at the first end EP1 of the light emitting element LD. Another one of the first and second semiconductor layers 11 and 13 may be disposed at the second end EP2 of the light emitting element LD. For example, the first semiconductor layer 11 may be disposed at the first end EP1 of the light emitting element LD, and the second semiconductor layer 13 may be disposed at the second end EP2 of the light emitting element LD.

According to an embodiment, the light emitting element LD may be a light emitting element manufactured in a pillar shape through an etching method or the like. In this specification, the pillar shape includes a rod-like shape or bar-like shape with an aspect ratio greater than 1, such as a circular pillar or a polygonal pillar, but a shape of the light emitting element LD is not particularly limited.

The light emitting element LD may have a size as small as nanometer scale to micrometer scale. The light emitting element LD may have a diameter D (or width) and/or length L ranging from nanometer scale to micrometer scale. For example, the length of the light emitting element LD may be less than or equal to about 50 μm. For example, the length of the light emitting element LD may be less than or equal to about 10 μm. For example, the length of the light emitting element LD may be less than or equal to about 5 μm. As such, in case that the size of the light emitting element LD is reduced, reliability problems may occur, such as a decrease in luminance due to damage to the surface of the light emitting element LD. Accordingly, the reliability of the light emitting element LD may be improved by increasing the emission wavelength of the light emitting element LD according to an embodiment. In an embodiment, the light emitting element LD may emit light with a wavelength in a range of about 464 nm to about 468 nm at a current density in a range of about 0.5 A/cm² to about 100 A/cm². For example, the light emitting element LD may emit light at the wavelength in a range of about 464 nm to about 468 nm at the current density of about 12 A/cm². In an embodiment, the indium content and thickness of the active layer 12 may be adjusted to increase the emission wavelength of the light emitting element LD. A detailed description of this will be provided below.

The first semiconductor layer 11 may be a semiconductor layer of a first conductive type. For example, the first semiconductor layer 11 may be a p-type semiconductor layer. For example, the first semiconductor layer 11 may include at least one of InAlGaN, GaN, AlGaN, InGaN, and AlN, and may be a p-type semiconductor layer doped with a first conductive dopant such as Mg, and the like. However, the material constituting the first semiconductor layer 11 is not limited thereto, and various other materials may constitute the first semiconductor layer 11.

The active layer 12 may be disposed between the first semiconductor layer 11 and the second semiconductor layer 13. The active layer 12 may include one of a single well structure, a multi well structure, a single quantum well structure, a multi quantum well (MQW) structure, a quantum dot structure, and a quantum wire structure, but the disclosure is limited thereto. The active layer 12 may include GaN, InGaN, InAlGaN, AlGaN, or AlN, and various other materials may constitute the active layer 12. In case that a voltage of a threshold voltage or more is applied to opposite ends of the light emitting element LD, the light emitting element LD may emit light while electron-hole pairs are coupled in the active layer 12. The light emitting element LD may be used as a light source of various light emitting elements including the pixel of the display device by controlling light emitting of light emitting element LD using this principle.

In an embodiment, the emission wavelength of the light emitting element LD may be increased by adjusting the indium content and thickness of the active layer 12. In an embodiment, the thickness of active layer 12 may be in a range of about 1.0 nm to about 2.8 nm. For example, the thickness of the active layer 12 may be in a range of about 1.0 nm to about 2.4 nm. The mole fraction of indium in the active layer 12 may be in a range of about 0.17 to about 0.20. For example, the mole fraction of indium in the active layer 12 may be in a range of about 0.18 to about 0.20. The indium (In) composition of the active layer 12 may have a uniform distribution in the direction of the length L of the light emitting element LD, but may have a different distribution in the direction of the diameter D of the light emitting element LD. As such, in case that the indium composition of the active layer 12 is formed non-uniformly in the direction of the diameter D of the light emitting element LD, it may be advantageous for improving the characteristics of the light emitting element LD. However, the disclosure is not necessarily limited thereto, and the indium composition of the active layer 12 may have various distributions in the direction of the length L or diameter D of the light emitting element LD.

In an embodiment, the indium content of the active layer 12 may be increased by lowering the growth temperature of the active layer 12, and the thickness of the active layer 12 may be reduced by reducing the growth time thereof, but the disclosure is not necessarily limited thereto.

As described above, by adjusting the indium content and thickness of the active layer 12, the current path toward the surface may be controlled to minimize the decrease in luminance due to surface damage and improve the reliability of the light emitting element LD.

The second semiconductor layer 13 may be disposed on the active layer 12, and may include a semiconductor layer of a different type from the first semiconductor layer 11. The second semiconductor layer 13 may include an n-type semiconductor layer. For example, the second semiconductor layer 13 may include at least one of InAlGaN, GaN, AlGaN, InGaN, and AlN, and may be an n-type semiconductor layer doped with a second conductive dopant such as Si, Ge, Sn, and the like. However, the material constituting the second semiconductor layer 13 is not limited thereto, and the second semiconductor layer 13 may be formed of various materials.

The electrode layer 14 may be disposed on the first end EP1 and/or the second end EP2 of the light emitting element LD. In FIG. 2, an embodiment in which the electrode layer 14 is formed on the first semiconductor layer 11 is illustrated, but the disclosure is not necessarily limited thereto. For example, a separate electrode layer may be further disposed on the second semiconductor layer 13.

The electrode layer 14 may include a transparent metal or a transparent metal oxide. For example, the electrode layer 14 may include at least one of indium tin oxide (ITO), indium zinc oxide (IZO), and zinc tin oxide (ZTO), but the disclosure is not necessarily limited thereto. As such, in case that the electrode layer 14 is made of a transparent metal or a transparent metal oxide, the light generated in the active layer 12 of the light emitting element LD may pass through the electrode layer 14 and be emitted to the outside of the light emitting element LD.

An insulating film INF may be provided on a surface of the light emitting element LD. The insulating film INF may be disposed (e.g., directly disposed) on the surfaces of the first semiconductor layer 11, the active layer 12, the second semiconductor layer 13, and/or the electrode layer 14. The insulating film INF may expose the first and second ends EP1 and EP2 of the light emitting element LD having different polarities.

The insulating film INF may prevent an electrical short that may occur in case that the active layer 12 contacts a conductive material other than the first and second semiconductor layers 11 and 13. The insulating film INF may improve lifespan and luminous efficiency of the light emitting elements LD by minimizing surface defects of the light emitting elements LD.

The insulating film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). For example, the insulating film INF may be composed of a double layer, and each layer constituting the double layer may include different materials. For example, the insulating film INF may be composed of a double layer composed of aluminum oxide (AlOₓ) and silicon oxide (SiOₓ), but the disclosure is not necessarily limited thereto. According to an embodiment, the insulating film INF may be omitted.

A light emitting element including the light emitting element LD may be used in various types of devices that require a light source, such as a display device. For example, the light emitting elements LD may be disposed in each pixel of a display panel, and the light emitting elements LD may be used as a light source for each pixel. However, the application field of the light emitting element LD is not limited to the examples described above. For example, the light emitting element LD may be also used in other types of devices that require a light source, such as a lighting device.

According to the above-described embodiment, the reliability of the light emitting element LD may be improved by increasing the emission wavelength of the light emitting element LD by adjusting the indium content and thickness of the active layer 12.

TABLE 1

| | 100 Hr | 500 Hr | 1000 Hr |
|---|---|---|---|
| Comparative | 94.9% | 82.9% | 69.8% |
| Example | | | |
| Example | 97.8% | 90.3% | 79.0% |

TABLE 2

| | Peak EQE |
|---|---|
| Comparative | 14.3 ± 0.5% |
| Example | |
| Example | 15.2 ± 0.9% |

Table 1 describes the evaluation of the luminance maintenance rate of the light emitting element depending on the driving time in the Comparative Example, which is a light emitting element that emits light at a 460 nm wavelength, and the Example, which is a light emitting element that emits light at a 466 nm wavelength. Table 2 describes the evaluation of the maximum external quantum efficiency of the light emitting element in the Comparative Example, which is a light emitting element that emits light at a 460 nm wavelength, and the Example, which is a light emitting element that emits light at a 466 nm wavelength.

Referring to the results in Tables 1 and 2, it can be seen that in the embodiment of the light emitting element of the Example, the luminance maintenance rate was improved under long-term driving conditions and the maximum external quantum efficiency was improved compared to the light emitting element of the Comparative Example.

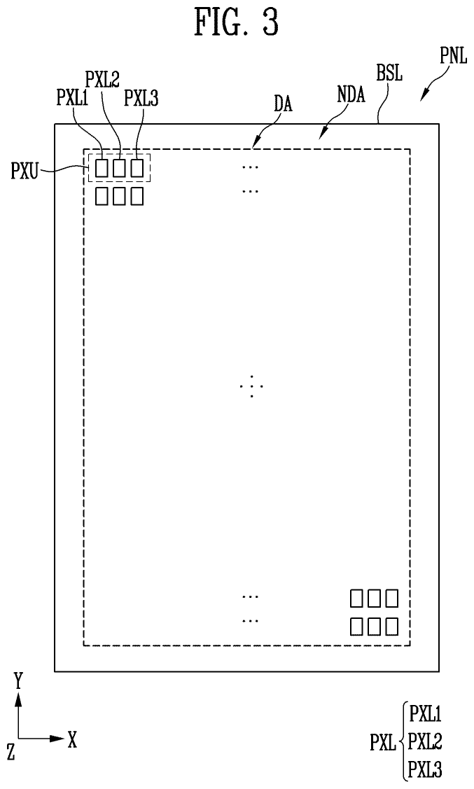

FIG. 3 is a plan view of a display device according to an embodiment.

In FIG. 3, a display device, in particular, a display panel PNL provided in the display device will be illustrated as an embodiment of an electronic device that can use the light emitting element LD described in the embodiments of FIGS. 1 and 2 as a light source.

For convenience of description, in FIG. 3, the structure of the display panel PNL will be briefly illustrated centering on the display area DA. However, according to embodiments, at least one driving circuit unit (e.g., at least one of a scan driver and a data driver), lines, and/or pads not shown may be further disposed on the display panel PNL.

Referring to FIG. 3, the display panel PNL and the base layer BSL for forming the display panel PNL may include a display area DA for displaying an image and a non-display area NDA excluding the display area DA. The display area DA may constitute a screen on which an image is displayed, and the non-display area NDA may be the remaining area excluding the display area DA.

A pixel unit PXU may be disposed in the display area DA. The pixel unit PXU may include a first pixel PXL1, a second pixel PXL2, and/or a third pixel PXL3. Hereinafter, when at least one of the first pixel PXL1, the second pixel PXL2, and the third pixel PXL3 is arbitrarily referred to, or when two or more types of pixels are collectively referred to, it will be referred to as “pixel PXL” or “pixels PXL”.

The pixels PXL may be regularly arranged according to a stripe or PENTILE™ arrangement structure. However, an arrangement of the pixels PXL is not limited thereto, and the pixels PXL may be arranged in the display area DA in various structures and/or ways.

According to an embodiment, two or more types of pixels PXL emitting light of different colors may be disposed in the display area DA. For example, in the display area DA, first pixels PXL1 emitting light of a first color, second pixels PXL2 emitting light of a second color, and third pixels PXL3 emitting light of a third color may be arranged in the display area DA. At least one of the first to third pixels PXL1, PXL2, and PXL3 disposed adjacent to each other may constitute one pixel unit PXU capable of emitting light of various colors. For example, each of the first to third pixels PXL1, PXL2, and PXL3 may be a pixel that emits light of a color. According to embodiments, the first pixel PXL1 may be a red pixel that emits red light, the second pixel PXL2 may be a green pixel that emits green light, and the third pixel PXL3 may be a blue pixel that emits blue light, but the disclosure is not limited thereto.

In an embodiment, the first pixel PXL1, the second pixel PXL2, and the third pixel PXL3 may have light emitting elements that emit light of the same color, but may include a color conversion layer and/or a color filter layer disposed on each light emitting element and having different colors, so may emit light of a first color, a second color, and a third color, respectively. In another embodiment, the first pixel PXL1, the second pixel PXL2, and the third pixel PXL3 may have a light emitting element of a first color, a light emitting element of a second color, and a light emitting element of a third color as a light source, respectively, so may also emit light of the first color, second color, and third color, respectively. However, the color, type, and/or number of pixels PXL constituting each pixel unit PXU are not particularly limited. The color of light emitted by each pixel PXL may be changed in various ways.

The pixel PXL may include at least one light source driven by a control signal (e.g., a scan signal and a data signal) and/or a power supply (e.g., a first power supply and a second power supply). In an embodiment, the light source may include at least one light emitting element LD according to an embodiment of FIGS. 1 and 2, for example, an ultra-small pillar type light emitting element LD having a size as small as nanometer scale to micrometer scale. However, the disclosure is not necessarily limited thereto, and various types of light emitting elements LD may be used as a light source of the pixel PXL.

In an embodiment, each pixel PXL may be formed of active pixels. However, the type, structure, and/or driving method of the pixels PXL applicable to the display device is not particularly limited. For example, each pixel PXL may be made of a pixel of a passive or active light emitting display device having various structures and/or driving methods.

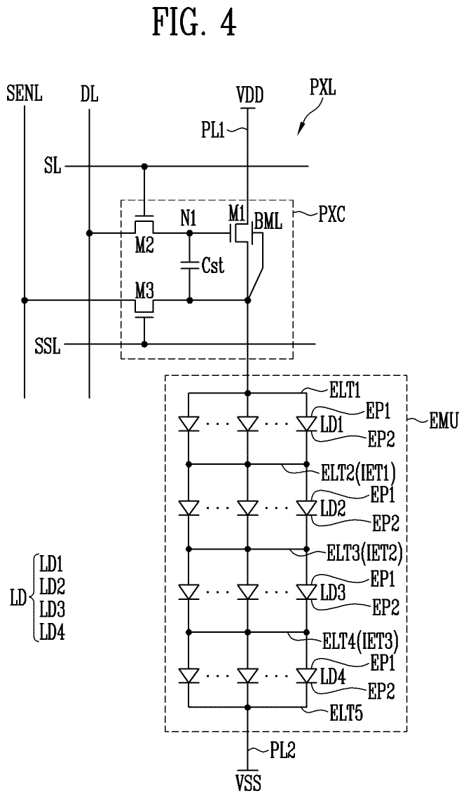

FIG. 4 is a schematic diagram of an equivalent circuit of a pixel according to an embodiment.

The pixel PXL shown in FIG. 4 may be one of the first pixel PXL1, the second pixel PXL2, and the third pixel PXL3 provided in the display panel PNL of FIG. 3. The first pixel PXL1, the second pixel PXL2, and the third pixel PXL3 may have substantially the same or similar structure.

Referring to FIG. 4, the pixel PXL may include a light emitting unit EMU for generating light of luminance corresponding to each data signal, and a pixel circuit PXC for driving the light emitting unit EMU.

The pixel circuit PXC may be connected between the first power supply VDD and the light emitting unit EMU. The pixel circuit PXC may be connected to a scan line SL and a data line DL of the corresponding pixel PXL, and may control the operation of the light emitting unit EMU in response to a scan signal and a data signal supplied from the scan line SL and data line DL. The pixel circuit PXC may be further selectively connected to a sensing signal line SSL and a sensing line SENL.

The pixel circuit PXC may include at least one transistor and at least one capacitor. For example, the pixel circuit PXC may include a first transistor M1, a second transistor M2, a third transistor M3, and a storage capacitor Cst.

The first transistor M1 may be connected between the first power supply VDD and the first connection electrode ELT1. A gate electrode of the first transistor M1 may be connected to the first node N1. The first transistor M1 may control a driving current supplied to the light emitting unit EMU in response to a voltage of the first node N1. The first transistor M1 may be a driving transistor that controls the driving current of the pixel PXL.

In an embodiment, the first transistor M1 may selectively include a lower conductive layer BML (also referred to as a “lower electrode”, “back gate electrode”, or “lower light blocking layer”). The gate electrode of the first transistor M1 and the lower conductive layer BML may overlap each other with an insulating layer interposed between the gate electrode of the first transistor M1 and the lower conductive layer BML. In an embodiment, the lower conductive layer BML may be connected to an electrode, for example, a source or drain electrode, of the first transistor M1.

In case that the first transistor M1 includes the lower conductive layer BML, a back-biasing technology (or sync technology) may be applied, the back-biasing technology moving the threshold voltage of the transistor M1 in a negative or positive direction by applying a back-biasing voltage to the lower conductive layer BML of the first transistor M1 when driving the pixel PXL. For example, by applying source-sink technology by connecting the lower conductive layer BML to the source electrode of the first transistor M1, the threshold voltage of the first transistor M1 may be moved in the negative or positive direction. In case that the lower conductive layer BML is disposed under the semiconductor pattern constituting the channel of the first transistor M1, the lower conductive layer BML may serve as a light blocking pattern and stabilize the operation characteristics of the first transistor M1. However, the function and/or utilization method of the lower conductive layer BML is not limited thereto.

The second transistor M2 may be connected between the data line DL and the first node N1. A gate electrode of the second transistor M2 may be connected to the scan line SL. The second transistor M2 may be turned on in case that a scan signal of the gate-on voltage (e.g., high level voltage) is supplied from the scan line SL, and may connect the data line DL and the first node N1.

In each frame period, the data signal of the corresponding frame may be supplied to the data line DL, and the data signal may be transmitted the first node N1 through the second transistor M2, which is turned on during the period in which the scan signal of the gate-on voltage is supplied. The second transistor M2 may be a switching transistor for transmitting each data signal into the pixel PXL.

An electrode of the storage capacitor Cst may be connected to the first node N1, and another electrode of the storage capacitor Cst may be connected to the second electrode of the first transistor M1. The storage capacitor Cst may be charged with a voltage corresponding to the data signal supplied to the first node N1 during each frame period.

The third transistor M3 may be connected between the first connection electrode ELT1 (or the second electrode of the first transistor M1) and the sensing line SENL. The gate electrode of the third transistor M3 may be connected to the sensing signal line SSL. The third transistor M3 may transmit a voltage value applied to the first connection electrode ELT1 to the sensing line SENL depending on the sensing signal supplied to the sensing signal line SSL. The voltage value transmitted through the sensing line SENL may be provided to an external circuit (e.g., timing controller), and the external circuit may extract characteristic information (e.g., the threshold voltage of the first transistor M1 of each pixel PXL) based on the provided voltage value. The extracted characteristic information may be used to convert image data so that a characteristic deviation between the pixels PXL may be compensated.

In FIG. 4, the transistors included in the pixel circuit PXC are all shown as n-type transistors, but the disclosure is not necessarily limited thereto. For example, at least one of the first, second, and third transistors M1, M2, and M3 may be a p-type transistor.

The structure and driving method of the pixel PXL may be changed in various ways. For example, the pixel circuit PXC may be composed of pixel circuits with various structures and/or driving methods, in addition to the embodiment shown in FIG. 4.

For example, the pixel circuit PXC may not include the third transistor M3. The pixel circuit PXC may further include other circuit elements such as a compensation transistor for compensating the threshold voltage of the first transistor M1, an initialization transistor for initializing a voltage of the first node N1 and/or the first connection electrode ELT1, a light emitting control transistor for controlling a period in which the driving current is supplied to the light emitting unit EMU, and/or a boosting capacitor for boosting the voltage of the first node N1.

The light emitting unit EMU may include at least one light emitting element LD connected between the first power supply VDD and the second power supply VSS, for example, multiple light emitting elements LD.

For example, the light emitting unit EMU may include a first connection electrode ELT1 connected to the first power supply VDD through the pixel circuit PXC and the first power line PL1, a fifth connection electrode ELT5 connected to the second power supply VSS through the second power line PL2, and multiple light emitting elements LD connected between the first and fifth connection electrodes ELT1 and ELT5.

The first power supply VDD and the second power supply VSS may have different potentials so that the light emitting elements LD can emit light. For example, the first power supply VDD may be set to a high potential power supply, and the second power supply VSS may be set to a low potential power supply.

In an embodiment, the light emitting unit EMU may include at least one series stage. Each series stage may include a pair of electrodes (e.g., two electrodes) and at least one light emitting element LD connected in the forward direction between the pair of electrodes. Here, the number of series stages constituting the light emitting unit EMU and the number of light emitting elements LD constituting each series stage are not particularly limited. For example, the number of light emitting elements LD constituting each series stage may be the same or different, and the number of light emitting elements LD is not particularly limited.

For example, the light emitting unit EMU may include a first series stage including at least one first light emitting element LD1, a second series stage including at least one second light emitting element LD2, a third series stage including at least one third light emitting element LD3, and a fourth series stage including at least one fourth light emitting element LD4.

The first series stage may include the first connection electrode ELT1 and the second connection electrode ELT2, and at least one first light emitting element LD1 connected between the first and second connection electrodes ELT1 and ELT2. Each first light emitting element LD1 may be connected in the forward direction between the first and second connection electrodes ELT1 and ELT2. For example, the first end EP1 of the first light emitting element LD1 may be connected to the first connection electrode ELT1, and the second end EP2 of the first light emitting element LD1 may be connected to the second connection electrode ELT2.

The second series stage may include the second connection electrode ELT2 and the third connection electrode ELT3, and at least one second light emitting element LD2 connected between the second and third connection electrodes ELT2 and ELT3. Each second light emitting element LD2 may be connected in the forward direction between the second and third connection electrodes ELT2 and ELT3. For example, the first end EP1 of the second light emitting element LD2 may be connected to the second connection electrode ELT2, and the second end EP2 of the second light emitting element LD2 may be connected to the third connection electrode ELT3.

The third series stage may include the third connection electrode ELT3 and the fourth connection electrode ELT4, and at least one third light emitting element LD3 connected between the third and fourth connection electrodes ELT3 and ELT4. Each third light emitting element LD3 may be connected in the forward direction between the third and fourth connection electrodes ELT3 and ELT4. For example, the first end EP1 of the third light emitting element LD3 may be connected to the third connection electrode ELT3, and the second end EP2 of the third light emitting element LD3 may be connected to the fourth connection electrode ELT4.

The fourth series stage may include the fourth connection electrode ELT4 and the fifth connection electrode ELT5, and at least one fourth light emitting element LD4 connected between the fourth and fifth connection electrodes ELT4 and ELT5. Each fourth light emitting element LD4 may be connected in the forward direction between the fourth and fifth connection electrodes ELT4 and ELT5. For example, the first end EP1 of the fourth light emitting element LD4 may be connected to the fourth connection electrode ELT4, and the second end EP2 of the fourth light emitting element LD4 may be connected to the fifth connection electrode ELT5.

The first electrode of the light emitting unit EMU, for example, the first connection electrode ELT1, may be an anode electrode of the light emitting unit EMU. The last electrode of the light emitting unit EMU, for example, the fifth connection electrode ELT5, may be a cathode electrode of the light emitting unit EMU.

The remaining electrodes of the light emitting unit EMU, for example, the second connection electrode ELT2, the third connection electrode ELT3, and/or the fourth connection electrode ELT4, may form intermediate electrodes. For example, the second connection electrode ELT2 may form the first intermediate electrode IET1, the third connection electrode ELT3 may form the second intermediate electrode IET2, and the fourth connection electrode ELT4 may form the third intermediate electrode IET3.

In case that the light emitting elements LD are connected in a series/parallel structure, power efficiency may be improved compared to the case that the same number of light emitting elements LD are connected only in parallel. In a pixel PXL in which light emitting elements LD are connected in a series/parallel structure, even in case that a short circuit defect occurs in some of the series stages, a certain luminance may be expressed through the light emitting elements LD of another one of the series stages, so the possibility of dark spot defects in the pixel PXL may be reduced. However, the disclosure is not necessarily limited thereto, and the light emitting unit EMU may be formed by connecting the light emitting elements LD only in series, or the light emitting unit EMU may be formed by connecting them only in parallel.

Each of the light emitting elements LD may include the first end EP1 (e.g., p-type end) connected to the first power supply VDD via at least one electrode (e.g., the first connection electrode ELT1), the pixel circuit PXC, and/or the first power line PL1, and the like, and the second end EP2 (e.g., n-type end) connected to the second power supply VSS via at least another electrode (e.g., the fifth connection electrode ELT5), and the second power line PL2. The light emitting elements LD may be connected in a forward direction between the first power supply VDD and the second power supply VSS. The light emitting elements LD connected in the forward direction may constitute effective light sources of the light emitting unit EMU.

In case that a driving current is supplied through the corresponding pixel circuit PXC, the light emitting elements LD may emit light with luminance corresponding to the driving current. For example, during each frame period, the pixel circuit PXC may supply a driving current corresponding to a gray scale value to be expressed in the corresponding frame to the light emitting unit EMU. Accordingly, while the light emitting elements LD emit light with luminance corresponding to the driving current, the light emitting unit EMU may express luminance corresponding to the driving current.

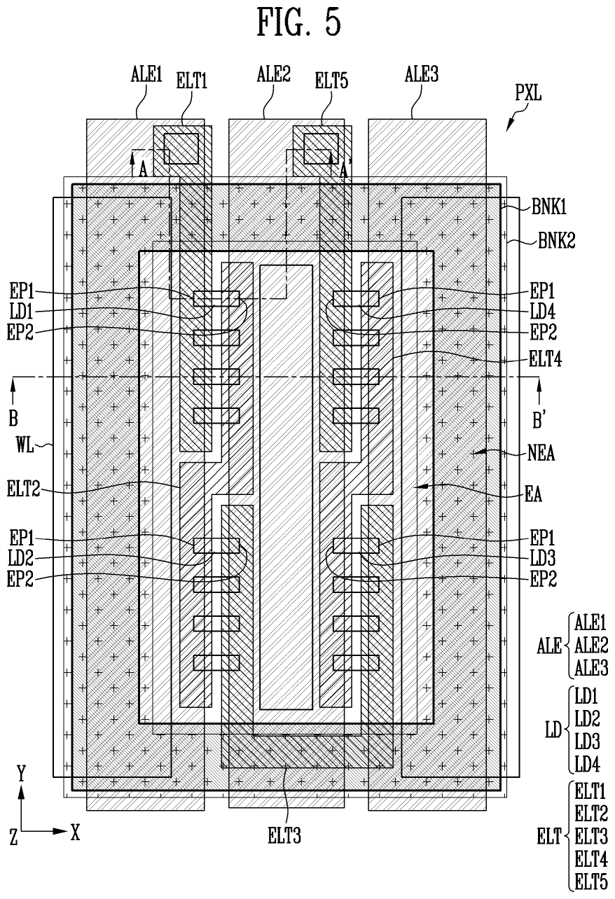

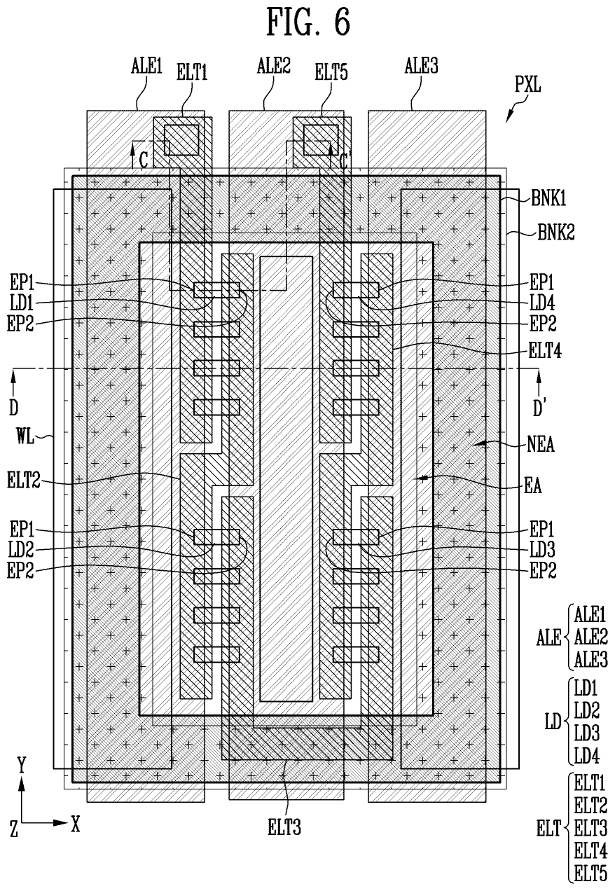

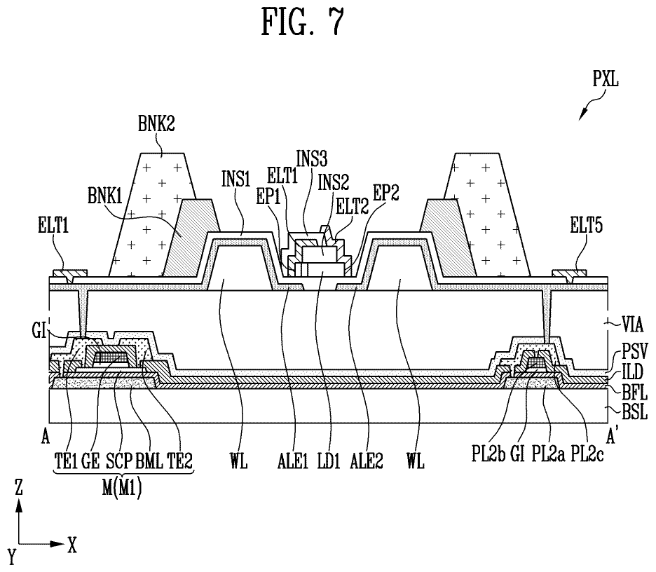

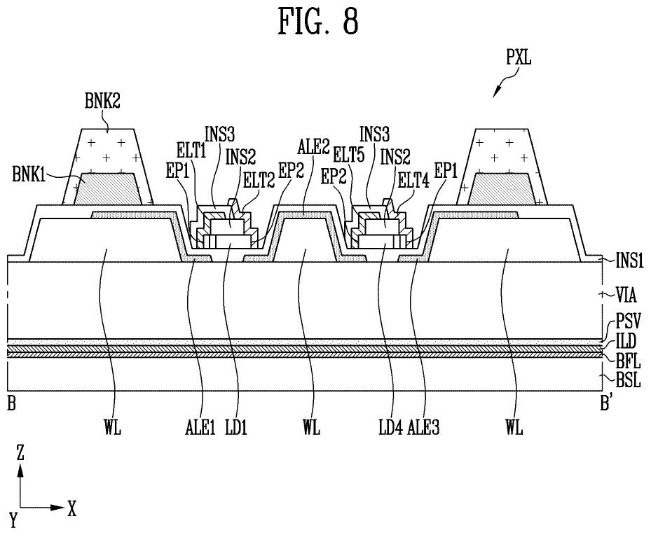

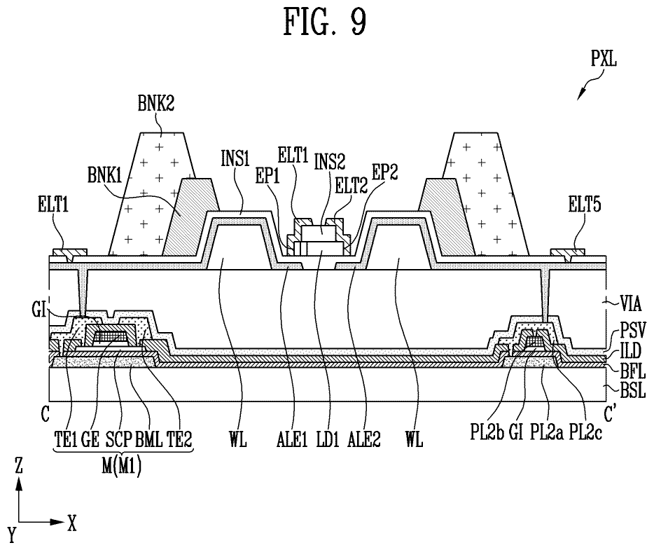

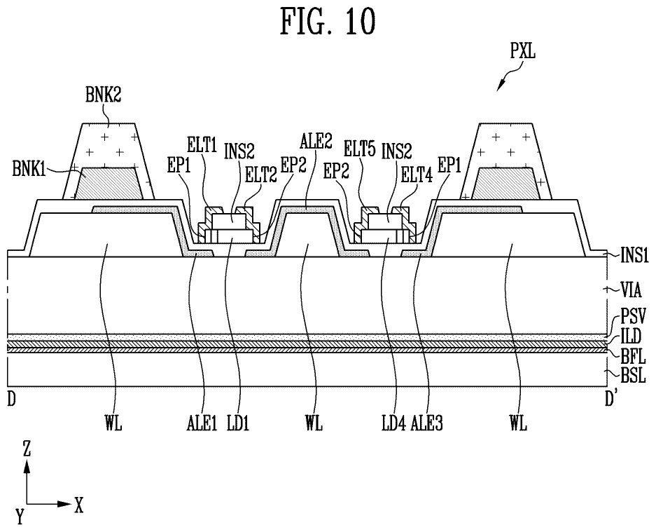

FIGS. 5 and 6 are plan views of pixels according to an embodiment. FIG. 7 is a schematic cross-sectional view taken along line A-A′ of FIG. 5. FIG. 8 is a schematic cross-sectional view taken along line B-B′ of FIG. 5. FIG. 9 is a schematic cross-sectional view taken along line C-C′ of FIG. 6. FIG. 10 is a schematic cross-sectional view taken along line D-D′ of FIG. 6.

For example, FIGS. 5 and 6 may be one of the first to third pixels PXL1, PXL2, and PXL3 constituting the pixel unit PXU of FIG. 3, and the first to third pixels PXL1, PXL2, and PXL3 may have structures that are substantially the same as or similar to each other. FIGS. 5 and 6 illustrate an embodiment in which each pixel PXL includes light emitting elements LD disposed in four series stages as shown in FIG. 4, but the number of series stages of each pixel PXL may change in various ways according to embodiments.

Hereinafter, when one or more light emitting elements among the first to fourth light emitting elements LD1, LD2, LD3, and LD4 are arbitrarily referred to, or when two or more types of light emitting elements are collectively referred to, it is referred to as “light emitting element LD” or “light emitting elements LD”. When arbitrarily referring to at least one electrode among electrodes including the first to third electrodes ALE1, ALE2, and ALE3, it is referred to as “electrode ALE” or “electrodes ALE”, and when arbitrarily referring to at least one electrode among electrodes including the first to fifth connection electrodes ELT1, ELT2, ELT3, ELT4, and ELT5, it is referred to as “connection electrode ELT” or “connection electrodes ELT”.

Referring to FIGS. 5 and 6, the pixel PXL may include an emission area EA and a non-emission area NEA. The emission area EA may include light emitting elements LD and may be an area capable of emitting light. The non-emission area NEA may surround the emission area EA in a plan view. The non-emission area NEA may be an area in which the first bank BNK1 surrounding the emission area EA is provided. The first bank BNK1 may be provided in the non-emission area NEA and disposed to at least partially surround the emission area EA in a plan view.

The first bank BNK1 may include an opening that overlaps the emission area EA in a plan view. The opening of the first bank BNK1 may provide a space where the light emitting elements LD can be provided in the step of supplying the light emitting elements LD to each pixel PXL. For example, a desired type and/or amount of light emitting element ink may be supplied to the space defined by the opening of the first bank BNK1.

The first bank BNK1 may include an organic material such as an acrylates resin, an epoxy resin, a phenolic resin, a polyamides resin, a polyimides resin, a polyesters resin, a polyphenylenesulfides resin, or benzocyclobutene (BCB). However, the disclosure is not necessarily limited thereto, and the first bank BNK1 may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

According to embodiments, the first bank BNK1 may include at least one light blocking and/or reflective material. Accordingly, the light leakage between adjacent pixels PXL may be prevented. For example, the first bank BNK1 may include at least one black pigment.

The second bank BNK2 may include an opening that overlaps the emission area EA in a plan view. The opening of the second bank BNK2 may provide a space where a color conversion layer, which will be described below, can be provided. For example, a desired type and/or amount of color conversion layer may be supplied to the space defined by the opening of the second bank BNK2.

The second bank BNK2 may include an organic material such as an acrylates resin, an epoxy resin, a phenolic resin, a polyamides resin, a polyimides resin, a polyesters resin, a polyphenylenesulfides resin, or benzocyclobutene (BCB). However, the disclosure is not necessarily limited thereto, and the second bank BNK2 may include various types of inorganic materials such as silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

According to embodiments, the second bank BNK2 may include at least one light blocking and/or reflective material. Accordingly, the light leakage between adjacent pixels PXL may be prevented. For example, the second bank BNK2 may include at least one black pigment.

The pixel PXL may include partition walls WL, electrodes ALE, light emitting elements LD, and/or connection electrodes ELT.

The partition walls WL may overlap the emission area EA and may be spaced apart from each other in a plan view. The partition walls WL may be at least partially disposed in the non-emission area NEA. The partition walls WL may extend in the second direction (Y-axis direction) and be spaced apart from each other in the first direction (X-axis direction).

Each of the partition walls WL may partially overlap at least one electrode ALE in the emission area EA. For example, the partition walls WL may be provided under the electrodes ALE, respectively. As the partition walls WL are provided under an area of each of the electrodes ALE, an area of each of the electrodes ALE may protrude toward an upper direction of the pixel PXL, for example, in the third direction (Z-axis direction) in the area where the partition walls WL are formed. In case that the partition walls WL and/or the electrodes ALE include a reflective material, a reflective wall structure may be formed around the light emitting elements LD. Accordingly, the light emitted from the light emitting elements LD may be emitted in the upper direction of the pixel PXL (e.g., the front direction of the display panel PNL including a viewing angle range), so the light output efficiency of the display panel PNL may be improved.

The electrodes ALE may be provided at least in the emission area EA. The electrodes ALE may extend in the second direction (Y-axis direction) and be spaced apart from each other in the first direction (X-axis direction).

Each of the first to third electrodes ALE1, ALE2, and ALE3 may extend in the second direction (Y-axis direction) and may be sequentially arranged and spaced apart in the first direction (X-axis direction). Some of the electrodes ALE may be connected to the pixel circuit (PXC in FIG. 4) and/or a power line through a contact hole. For example, the first electrode ALE1 may be connected to the pixel circuit PXC and/or the first power line PL1 through a contact hole, and the second electrode ALE2 may be connected to the second power line PL2 through a contact hole.

According to embodiments, some of the electrodes ALE may be electrically connected to some of the connecting electrodes ELT through a contact hole. For example, the first electrode ALE1 may be electrically connected to the first connection electrode ELT1 through a contact hole, and the second electrode ALE2 may be electrically connected to the fifth connection electrode ELT5 through a contact hole.

A pair of electrodes ALE adjacent to each other may receive different signals in the alignment step of the light emitting elements LD. For example, in case that the first to third electrodes ALE1, ALE2, and ALE3 are sequentially arranged in the first direction (X-axis direction), the first electrode ALE1 and the second electrode ALE2 may receive alignment signals different from each other, and the second electrode ALE2 and the third electrode ALE3 may receive alignment signals different from each other.

Each of the light emitting elements LD may be aligned between a pair of adjacent electrodes ALE in the emission area EA. Each of the light emitting elements LD may be electrically connected between a pair of adjacent connection electrodes ELT.

The first light emitting element LD1 may be aligned between the first and second electrodes ALE1 and ALE2. The first light emitting element LD1 may be electrically connected between the first and second connection electrodes ELT1 and ELT2. For example, the first light emitting element LD1 may be aligned in the first area (e.g., upper area) of the first and second electrodes ALE1 and ALE2, the first end EP1 of the first light emitting element LD1 may be electrically connected to the first connection electrode ELT1, and the second end EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the second and third connection electrodes ELT2 and ELT3. For example, the second light emitting element LD2 may be aligned in the second area (e.g., lower area) of the first and second electrodes ALE1 and ALE2, the first end EP1 of the second light emitting element LD2 may be electrically connected to the second connection electrode ELT2, and the second end EP2 of the second light emitting element LD2 may be electrically connected to the third connection electrode ELT3.

The third light emitting element LD3 may be aligned between the second and third electrodes ALE2 and ALE3. The third light emitting element LD3 may be electrically connected between the third and fourth connection electrodes ELT3 and ELT4. For example, the third light emitting element LD3 may be aligned in the second area (e.g., lower area) of the second and third electrodes ALE2 and ALE3, the first end EP1 of the third light emitting element LD3 may be electrically connected to the third connection electrode ELT3, and the second end EP2 of the third light emitting element LD3 may be electrically connected to the fourth connection electrode ELT4.

The fourth light emitting element LD4 may be aligned between the second and third electrodes ALE2 and ALE3. The fourth light emitting element LD4 may be electrically connected between the fourth and fifth connection electrodes ELT4 and ELT5. For example, the fourth light emitting element LD4 may be aligned in the first area (e.g., upper area) of the second and third electrodes ALE2 and ALE3, the first end EP1 of the fourth light emitting element LD4 may be electrically connected to the fourth connection electrode ELT4, and the second end EP2 of the fourth light emitting element LD4 may be electrically connected to the fifth connection electrode ELT5.

For example, the first light emitting element LD1 may be disposed in the left upper area of the emission area EA, and the second light emitting element LD2 may be disposed in the left lower area of the emission area EA. The third light emitting element LD3 may be disposed in the right lower area of the emission area EA, and the fourth light emitting element LD4 may be disposed in the right upper area of the emission area EA. However, the arrangement and/or connection structure of the light emitting elements LD may change in various ways depending on the structure of the light emitting unit EMU and/or the number of series stages.

Each of the connection electrodes ELT may be provided in at least the emission area EA and may be arranged to overlap at least one electrode ALE and/or the light emitting element LD in a plan view. For example, the connection electrodes ELT may be formed on the electrodes ALE and/or the light emitting elements LD to overlap the electrodes ALE and/or the light emitting elements LD in a plan view, respectively, and may be electrically connected to light emitting elements LD.

The first connection electrode ELT1 may be disposed on the first area (e.g., upper area) of the first electrode ALE1 and the first ends EP1 of the first light emitting elements LD1 to be electrically connected to the first ends EP1 of the first light emitting elements LD1.

The second connection electrode ELT2 may be disposed on the first area (e.g., upper area) of the second electrode ALE2 and the second ends EP2 of the first light emitting elements LD1 to be electrically connected to the second ends EP2 of the first light emitting elements LD1. The second connection electrode ELT2 may be disposed on the second area (e.g., lower area) of the first electrode ALE1 and the first ends EP1 of the second light emitting elements LD2 to be electrically connected to the first ends EP1 of the second light emitting elements LD2. For example, the second connection electrode ELT2 may electrically connect the second ends EP2 of the first light emitting elements LD1 and the first ends EP1 of the second light emitting elements LD2 in the emission area EA. To this end, the second connection electrode ELT2 may have a bent shape. For example, the second connection electrode ELT2 may have an angular or curved structure at the boundary between the area where at least one first light emitting element LD1 is arranged and the area where at least one second light emitting element LD2 is arranged.

The third connection electrode ELT3 may be disposed on the second area (e.g., lower area) of the second electrode ALE2 and the second ends EP2 of the second light emitting elements LD2 to be electrically connected to the second ends EP2 of the second light emitting elements LD2. The third connection electrode ELT3 may be disposed on the second area (e.g., lower area) of the third electrode ALE3 and the first ends EP1 of the third light emitting elements LD3 to be electrically connected to the first ends EP1 of the third light emitting elements LD3. For example, the third connection electrode ELT3 may electrically connect the second ends EP2 of the second light emitting elements LD2 and the first ends EP1 of the third light emitting elements LD3 in the emission area EA. To this end, the third connection electrode ELT3 may have a bent shape. For example, the third connection electrode ELT3 may have an angular or curved structure at the boundary between the area where at least one second light emitting element LD2 is arranged and the area where at least one third light emitting element LD3 is arranged.

The fourth connection electrode ELT4 may be disposed on the second area (e.g., lower area) of the second electrode ALE2 and the second ends EP2 of the third light emitting elements LD3 to be electrically connected to the second ends EP2 of the third light emitting elements LD3. The fourth connection electrode ELT4 may be disposed on the first area (e.g., upper area) of the third electrode ALE3 and the first ends EP1 of the fourth light emitting elements LD4 to be electrically connected to the first ends EP1 of the fourth light emitting elements LD4. For example, the fourth connection electrode ELT4 may electrically connect the second ends EP2 of the third light emitting elements LD3 and the first ends EP1 of the fourth light emitting elements LD4 in the emission area EA. To this end, the fourth connection electrode ELT4 may have a bent shape. For example, the fourth connection electrode ELT4 may have an angular or curved structure at the boundary between the area where at least one third light emitting element LD3 is arranged and the area where at least one fourth light emitting element LD4 is arranged.

The fifth connection electrode ELT5 may be disposed on the first area (e.g., upper area) of the second electrode ALE2 and the second ends EP2 of the fourth light emitting elements LD4 to be electrically connected to the second ends EP2 of the fourth light emitting elements LD4.

The first connection electrode ELT1, the third connection electrode ELT3, and/or the fifth connection electrode ELT5 may be made of a same conductive layer. The second connection electrode ELT2 and the fourth connection electrode ELT4 may be made of a same conductive layer. For example, as shown in FIG. 9, the connection electrodes ELT may be made of multiple conductive layers. The first connection electrode ELT1, the third connection electrode ELT3, and/or the fifth connection electrode ELT5 may be made of a first conductive layer, and the second connection electrode ELT2 and the fourth connection electrode ELT4 may be made of a second conductive layer which is different from the first conductive layer. In another embodiment, as shown in FIG. 10, the first to fifth connection electrodes ELT1, ELT2, ELT3, ELT4, and ELT5 may be made of a same conductive layer.

In the above-described embodiment, the light emitting elements LD aligned between the electrodes ALE may be connected in a desired shape using the connecting electrodes ELT. For example, the first light emitting elements LD1, the second light emitting elements LD2, the third light emitting elements LD3, and the fourth light emitting elements LD4 may be connected sequentially in series using the connection electrodes ELT.

Hereinafter, a cross-sectional structure of the pixel PXL will be described in detail with reference to FIGS. 7 to 10. FIGS. 7 to 10 show the first transistor M1 among various circuit elements constituting the pixel circuit (PXC in FIG. 4), and when it is not necessary for separately indicating the first to third transistors M1, M2, and M3, they will be collectively referred to as “transistor M”. The structure and/or arrangement of each layer of the transistors M are not limited to the embodiments shown in FIGS. 7 and 10 and may change in various ways according to embodiments.

The pixels PXL according to an embodiment may include circuit elements including transistors M disposed on the base layer BSL and various lines connected to the transistors M. On the circuit elements, the electrodes ALE, the light emitting elements LD, the connection electrodes ELT, a first bank BNK1, and/or second bank BNK2 constituting the light emitting unit EMU may be disposed.

The base layer BSL may constitute a base member and may be a rigid or flexible substrate or film. For example, the base layer BSL may be a rigid substrate made of glass or tempered glass, a flexible substrate (or thin film) made of plastic or metal, or at least one layer of insulating layer. The material and/or physical properties of the base layer BSL are not particularly limited. In embodiments, the base layer BSL may be substantially transparent. Here, “substantially transparent” may mean that light can be transmitted beyond a transmittance (predetermined or selectable). In another embodiment, the base layer BSL may be translucent or opaque. The base layer BSL may include a reflective material.

A lower conductive layer BML and a first power conductive layer PL2a may be disposed on the base layer BSL. The lower conductive layer BML and the first power conductive layer PL2a may be disposed on a same layer. For example, the lower conductive layer BML and the first power conductive layer PL2a may be formed simultaneously in a same process, but the disclosure is not necessarily limited thereto. The first power conductive layer PL2a may form the second power line PL2 described with reference to FIG. 4 and the like.

Each of the lower conductive layer BML and the first power conductive layer PL2a may be formed as a single layer or multiple layers that are made of molybdenum (Mo), copper (Cu), aluminum (Al), chromium (Cr), gold (Au), titanium (Ti), nickel (Ni), neodymium (Nd), indium (In), tin (Sn), and oxides or alloys thereof.

A buffer layer BFL may be disposed on the lower conductive layer BML and the first power conductive layer PL2a. The buffer layer BFL may prevent impurities from diffusing into circuit elements. The buffer layer BFL may be formed of a single layer, or may also be formed of multiple layers which are at least double layers. In case that the buffer layer BFL is formed of multiple layers, each layer may be formed of a same material or may be formed of different materials.

A semiconductor pattern SCP may be disposed on the buffer layer BFL. For example, the semiconductor pattern SCP may have a first region contacting the first transistor electrode TE1, a second region contacting the second transistor electrode TE2, and a channel region disposed between the first and second regions. According to an embodiment, one of the first and second regions may be a source region and another one of the first and second regions may be a drain region.

According to embodiments, the semiconductor pattern SCP may be made of polysilicon, amorphous silicon, oxide semiconductor, etc. The channel region of the semiconductor pattern SCP may be a semiconductor pattern that is not doped with impurities and may be an intrinsic semiconductor, and each of the first and second regions of the semiconductor pattern SCP may be a semiconductor doped with impurities.

A gate insulating layer GI may be disposed on the buffer layer BFL and the semiconductor pattern SCP. For example, the gate insulating layer GI may be disposed between the semiconductor pattern SCP and the gate electrode GE. The gate insulating layer GI may be disposed between the buffer layer BFL and the second power conductive layer PL2b. The gate insulating layer GI may be composed of a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The gate electrode GE of the transistor M and the second power conductive layer PL2b may be disposed on the gate insulating layer GI. The gate electrode GE and the second power conductive layer PL2b may be disposed on a same layer. For example, the gate electrode GE and the second power conductive layer PL2b may be formed simultaneously in a same process, but the disclosure is not limited thereto. The gate electrode GE may overlap the semiconductor pattern SCP in the third direction (Z-axis direction) on the gate insulating layer GI. The second power conductive layer PL2b may overlap the first power conductive layer PL2a in the third direction (Z-axis direction) on the gate insulating layer GI. The second power conductive layer PL2b, together with the first power conductive layer PL2a, may constitute the second power line PL2 described with reference to FIG. 4 and the like.

Each of the gate electrode GE and the second power conductive layer PL2b may be formed of a single layer or multiple layers that are made of molybdenum (Mo), copper (Cu), aluminum (Al), chromium (Cr), gold (Au), titanium (Ti), nickel (Ni), neodymium (Nd), indium (In), tin (Sn), or oxides or alloys thereof. For example, each of the gate electrode GE and the second power conductive layer PL2b may be formed of multiple layers of sequentially or repeatedly stacked titanium (Ti), copper (Cu), and/or indium tin oxide (ITO).

An interlayer insulating layer ILD may be disposed on the gate electrode GE and the second power conductive layer PL2b. For example, the interlayer insulating layer ILD may be disposed between the gate electrode GE and the first and second transistor electrodes TE1 and TE2. The interlayer insulating layer ILD may be disposed between the second power conductive layer PL2b and the third power conductive layer PL2c.

The interlayer dielectric layer ILD may be composed of a single layer or multiple layers, and may include various types of inorganic materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The first and second transistor electrodes TE1 and TE2 of the transistor M and the third power conductive layer PL2c may be disposed on the interlayer insulating layer ILD. The first and second transistor electrodes TE1 and TE2 and the third power conductive layer PL2c may be disposed on a same layer. For example, the first and second transistor electrodes TE1 and TE2 and the third power conductive layer PL2c may be formed simultaneously in a same process, but the disclosure is not limited thereto.

The first and second transistor electrodes TE1 and TE2 may overlap the semiconductor pattern SCP in the third direction (Z-axis direction). The first and second transistor electrodes TE1 and TE2 may be electrically connected to the semiconductor pattern SCP. For example, the first transistor electrode TE1 may be electrically connected to the first region of the semiconductor pattern SCP through a contact hole penetrating the interlayer insulating layer ILD. The first transistor electrode TE1 may be electrically connected to the lower conductive layer BML through a contact hole penetrating the interlayer insulating layer ILD and the buffer layer BFL. The second transistor electrode TE2 may be electrically connected to the second region of the semiconductor pattern SCP through a contact hole penetrating the interlayer insulating layer ILD. According to embodiments, one of the first and second transistor electrodes TE1 and TE2 may be a source electrode, and another of the first and second transistor electrodes TE1 and TE2 may be a drain electrode.

The third power conductive layer PL2c may overlap the first power conductive layer PL2a and/or the second power conductive layer PL2b in the third direction (Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole penetrating the interlayer insulating layer ILD and the buffer layer BFL. The third power conductive layer PL2c may be electrically connected to the second power conductive layer PL2b through a contact hole penetrating the interlayer insulating layer ILD. The third power conductive layer PL2c may constitute the second power line PL2 described with reference to FIG. 4 together with the first power conductive layer PL2a and/or the second power conductive layer PL2b.

The first and second transistor electrodes TE1 and TE2 and the third power conductive layer PL2c may be formed of a single layer or multiple layers that are made of molybdenum (Mo), copper (Cu), aluminum (Al), chromium (Cr), gold (Au), titanium (Ti), nickel (Ni), neodymium (Nd), indium (In), tin (Sn), or oxides or alloys thereof.

A protective layer PSV may be disposed on the first and second transistor electrodes TE1 and TE2 and the third power conductive layer PL2c. The protective layer PSV may be composed of a single layer or multiple layers, and may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

A via layer VIA may be disposed on the protective layer PSV. The via layer VIA may be made of an organic material to planarize the lower step. For example, the via layer VIA may include an organic material such as an acrylates resin, an epoxy resin, a phenolic resin, a polyamides resin, a polyimides resin, a polyester resin, a polyphenylenesulfides resin, or benzocyclobutene (BCB). However, the disclosure is not necessarily limited thereto, and the via layer VIA may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The partition walls WL may be disposed on the via layer VIA. The partition walls WL may serve to form a step so that the light emitting elements LD can be readily aligned in the emission area EA.

The partition walls WL may have various shapes according to embodiments. In an embodiment, the partition walls WL may have a shape that protrudes from the base layer BSL in the third direction (Z-axis direction). The partition walls WL may be formed to have an inclined surface inclined at an angle with respect to the base layer BSL. However, the disclosure is not necessarily limited thereto, and the partition walls WL may have side walls such as a curved surface or a step shape. For example, the partition walls WL may have a cross-section such as a semicircular or semielliptical shape.

The partition walls WL may include at least one organic material and/or an inorganic material. For example, the partition walls WL may include an organic material such as an acrylates resin, an epoxy resin, a phenolic resin, a polyamides resin, a polyimides resin, a polyester resin, a polyphenylenesulfides resin, or benzocyclobutene (BCB). However, the disclosure is not necessarily limited thereto, and the partition walls WL may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The electrodes ALE may be disposed on the via layer VIA and the partition walls WL. The electrodes ALE may at least partially cover the side surfaces and/or upper surfaces of the partition walls WL. The electrodes ALE disposed on the partition walls WL may have a shape corresponding to the partition walls WL. For example, the electrodes ALE disposed on the partition walls WL may include an inclined surface or curved surface corresponding to the shape of the partition walls WL. The partitions WL and the electrodes ALE may be reflective members that reflect the light emitted from the light emitting elements LD and may guide the light in the front direction of the pixel PXL, for example, in the third direction (Z-axis direction), so the light output efficiency of the display panel PNL can be improved.

The electrodes ALE may be spaced apart from each other. The electrodes ALE may be disposed on a same layer. For example, the electrodes ALE may be formed simultaneously in a same process, but the disclosure is not necessarily limited thereto.

The electrodes ALE may receive an alignment signal in an alignment step of the light emitting elements LD. Accordingly, an electric field may be formed between the electrodes ALE so that the light emitting elements LD provided in each pixel PXL can be aligned between the electrodes ALE.

The electrodes ALE may include at least one conductive material. For example, the electrodes ALE may include at least one of a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), etc., or alloy thereof, a conductive oxide material such as indium tin oxide (ITO), an indium zinc oxide conductive oxide such as (IZO), indium tin zinc oxide (ITZO), aluminum zinc oxide (AZO), gallium zinc oxide (GZO), zinc tin oxide (ZTO), or gallium tin oxide (GTO), and a conductive polymer such as PEDOT, but the disclosure is not necessarily limited thereto.

The first electrode ALE1 may be electrically connected to the first transistor electrode TE1 of the transistor M through a contact hole penetrating the via layer VIA and the protective layer PSV. The second electrode ALE2 may be electrically connected to the third power conductive layer PL2c through a contact hole penetrating the via layer VIA and the protective layer PSV.

A first insulating layer INS1 may be disposed on the electrodes ALE. The first insulating layer INS1 may be composed of a single layer or multiple layers, and may include an inorganic material including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The first bank BNK1 may be disposed on the first insulating layer INS1. The first bank BNK1 may include an opening that overlaps the emission area EA in a plan view. The opening of the first bank BNK1 may provide a space where the light emitting elements LD can be provided in the step of supplying the light emitting elements LD to each pixel PXL. For example, a desired type and/or amount of light emitting element ink may be supplied to the space defined by the opening of the first bank BNK1.

The first bank BNK1 may include an organic material such as an acrylates resin, an epoxy resin, a phenolic resin, a polyamides resin, a polyimides resin, a polyesters resin, a polyphenylenesulfides resin, or benzocyclobutene (BCB). However, the disclosure is not necessarily limited thereto, and the first bank BNK1 may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The light emitting elements LD may be disposed between the electrodes ALE. The light emitting elements LD may be bias-aligned between the electrodes ALE. For example, the light emitting elements LD may be bias-aligned so that the first end EP1 (or first semiconductor layer) may overlap the first electrode ALE1 in a plan view, and the second end EP2 (or second semiconductor layer) may overlap the second electrode ALE2 in a plan view.

The light emitting elements LD may be provided in the opening of the first bank BNK1 and disposed between the partition walls WL. The light emitting elements LD may be prepared in a dispersed form in a light emitting element ink and supplied to each pixel PXL through an inkjet printing method or the like. For example, the light emitting elements LD may be dispersed in a volatile solvent and provided to each pixel PXL. In case that an alignment signal is supplied to the electrodes ALE, an electric field may be formed between the electrodes ALE, so that the light emitting elements LD can be aligned between the electrodes ALE. After the light emitting elements LD are aligned, the solvent may be volatilized or removed by other methods to stably arrange the light emitting elements LD between the electrodes ALE.

A second insulating layer INS2 may be disposed on the light emitting elements LD. For example, the second insulating layer INS2 may be partially provided on the light emitting elements LD and expose the first and second ends EP1 and EP2 of the light emitting elements LD. In case that the second insulating layer INS2 is formed on the light emitting elements LD after the alignment of the light emitting elements LD is completed, the light emitting elements LD may be prevented from leaving the aligned position.

The second insulating layer INS2 may be composed of a single layer or multiple layers, and may include an inorganic material including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The connection electrodes ELT may be disposed on the first and second ends EP1 and EP2 of the light emitting elements LD exposed by the second insulating layer INS2. The first connection electrode ELT1 may be disposed (e.g., directly disposed) on the first end EP1 of the first light emitting elements LD1, and may contact the first end EP1 (or first semiconductor layer) of the first light emitting elements LD1.

The second connection electrode ELT2 may be disposed (e.g., directly disposed) on the second end EP2 (or second semiconductor layer) of the first light emitting elements LD1, and may contact the second end EP2 (or second semiconductor layer) of the first light emitting elements LD1. The second connection electrode ELT2 may be disposed (e.g., directly disposed) on the first end EP1 (or first semiconductor layer) of the second light emitting elements LD2, and may contact the first end EP1 (or first semiconductor layer) of the second light emitting elements LD2. The second connection electrode ELT2 may electrically connect the second end EP2 (or second semiconductor layer) of the first light emitting elements LD1 and the first end EP1 (or first semiconductor layer) of the second light emitting elements LD2.

Similarly, the third connection electrode ELT3 may be disposed (e.g., directly disposed) on the second end EP2 (or second semiconductor layer) of the second light emitting elements LD2, and may contact the second end EP2 (or second semiconductor layer) of the second light emitting elements LD2. The third connection electrode ELT3 may be disposed (e.g., directly disposed) on the first end EP1 (or first semiconductor layer) of the third light emitting elements LD3, and may contact the first end EP1 (or first semiconductor layer) of the third light emitting elements LD3. The third connection electrode ELT3 may electrically connect the second end EP2 (or second semiconductor layer) of the second light emitting elements LD2 and the first end EP1 (or first semiconductor layer) of the third light emitting elements LD3.

Similarly, the fourth connection electrode ELT4 may be disposed (e.g., directly disposed) on the second end EP2 (or second semiconductor layer) of the third light emitting elements LD3, and may contact the second end EP2 (or second semiconductor layer) of the third light emitting elements LD3. The fourth connection electrode ELT4 may be disposed (e.g., directly disposed) on the first end EP1 (or first semiconductor layer) of the fourth light emitting elements LD4, and may contact the first end EP1 (or first semiconductor layer) of the fourth light emitting elements LD4. The fourth connection electrode ELT4 may electrically connect the second end EP2 (or second semiconductor layer) of the third light emitting elements LD3 and the first end EP1 (or first semiconductor layer) of the fourth light emitting elements LD4.

The fifth connection electrode ELT5 may be disposed (e.g., directly disposed) on the second end EP2 (or second semiconductor layer) of the fourth light emitting elements LD4, and may contact the second end EP2 (or second semiconductor layer) of the fourth light emitting elements LD4.

The first connection electrode ELT1 may be electrically connected to the first electrode ALE1 through a contact hole penetrating the first insulating layer INS1. The fifth connection electrode ELT5 may be electrically connected to the second electrode ALE2 through a contact hole penetrating the first insulating layer INS1.

In an embodiment, the connection electrodes ELT may be composed of multiple conductive layers. For example, as shown in FIGS. 7 and 8, the first connection electrode ELT1, the third connection electrode ELT3, and the fifth connection electrode ELT5 may be disposed on a same layer. The second connection electrode ELT2 and the fourth connection electrode ELT4 may be disposed on a same layer. The first connection electrode ELT1, the third connection electrode ELT3, and the fifth connection electrode ELT5 may be disposed on the second insulating layer INS2. A third insulating layer INS3 may be disposed on the first connection electrode ELT1, the third connection electrode ELT3, and the fifth connection electrode ELT5. The second connection electrode ELT2 and the fourth connection electrode ELT4 may be disposed on the third insulating layer INS3.

As such, in case that the third insulating layer INS3 is disposed between the connection electrodes ELT made of different conductive layers, the connection electrodes ELT may be stably separated by the third insulating layer INS3. Therefore, electrical stability between the first and second ends EP1 and EP2 of the light emitting elements LD may be secured.

The third insulating layer INS3 may be composed of a single layer or multiple layers, and may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

In another embodiment, the connection electrodes ELT may be composed of a same conductive layer. For example, as shown in FIGS. 9 and 10, the first to fifth connection electrodes ELT1, ELT2, ELT3, ELT4, and ELT5 may be disposed on a same layer. For example, the first to fifth connection electrodes ELT1, ELT2, ELT3, ELT4, and ELT5 may be formed simultaneously in a same process. As such, in case that the connection electrodes ELT are formed simultaneously, the number of masks may be reduced and the manufacturing process may be simplified.

The connection electrodes ELT may be made of a transparent conductive material. For example, the connection electrodes ELT may include at least one of indium tin oxide (ITO), indium zinc oxide (IZO), indium tin zinc oxide (ITZO), aluminum zinc oxide (AZO), gallium zinc oxide (GZO), zinc tin oxide (ZTO), and gallium tin oxide (GTO), and may be implemented to be substantially transparent or translucent to satisfy a light transmittance (predetermined or selectable). Accordingly, the light emitted from the first and second ends EP1 and EP2 of the light emitting elements LD may pass through the connection electrodes ELT and be emitted to the outside of the display panel PNL.

The second bank BNK2 may be disposed on the first bank BNK1. The second bank BNK2 may be disposed in the non-emission area NEA.

The second bank BNK2 may include an opening that overlaps the emission area EA in a plan view. The opening of the second bank BNK2 may provide a space where a color conversion layer, which will be described below, can be provided. For example, a desired type and/or amount of color conversion layer may be supplied to the space defined by the opening of the second bank BNK2.

The second bank BNK2 may include an organic material such as an acrylates resin, an epoxy resin, a phenolic resin, a polyamides resin, a polyimides resin, a polyesters resin, a polyphenylenesulfides resin, or benzocyclobutene (BCB). However, the disclosure is not necessarily limited thereto, and the second bank BNK2 may include an inorganic material including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

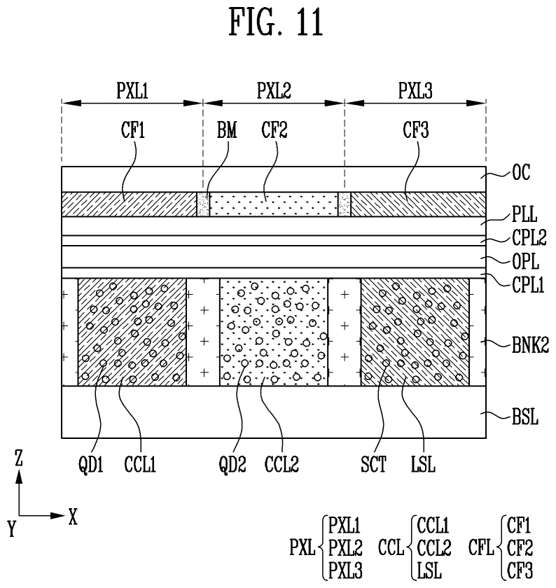

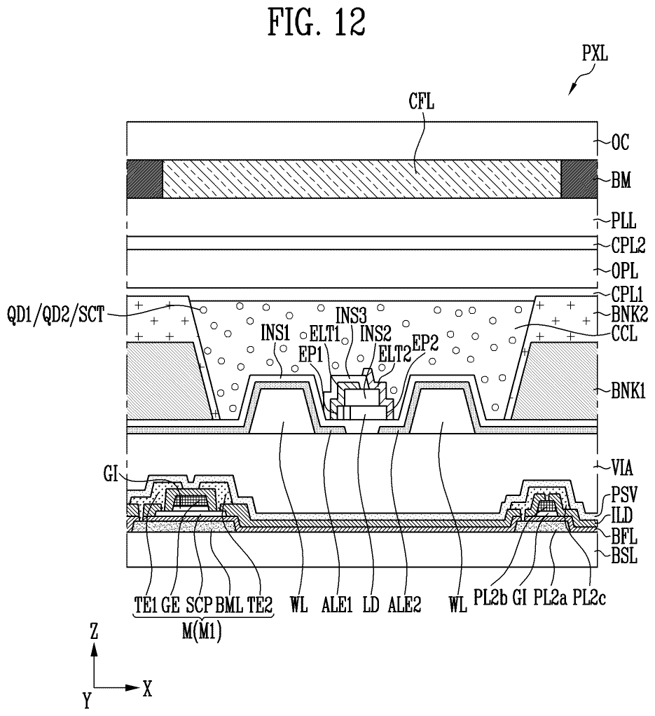

FIG. 11 is a schematic cross-sectional view of first to third pixels according to an embodiment. FIG. 12 is a schematic cross-sectional view of a pixel according to an embodiment.

FIG. 11 shows a color conversion layer CCL, an optical layer OPL, and/or a color filter layer CFL, etc. In FIG. 11, for convenience of description, constitution elements other than the base layer BSL and the second bank BNK2 of FIGS. 7 to 10 are omitted. FIG. 11 shows in detail the stacked structure of the pixel PXL in relation to the color conversion layer CCL, the optical layer OPL, and/or the color filter layer CFL.

Referring to FIGS. 11 and 12, the second bank BNK2 may be disposed between or at the boundary of the first to third pixels PXL1, PXL2, and PXL3, and may include the opening overlapping each of the first to third pixels PXL1, PXL2, and PXL3 in a plan view. The opening of the second bank BNK2 may provide a space where the color conversion layer CCL can be provided.

The color conversion layer CCL may be disposed on the light emitting elements LD in the opening of the second bank BNK2. The color conversion layer CCL may include a first color conversion layer CCL1 disposed in the first pixel PXL1, a second color conversion layer CCL2 disposed in the second pixel PXL2, and a scattering layer LSL disposed in the third pixel PXL3.

In an embodiment, the first to third pixels PXL1, PXL2, and PXL3 may include the light emitting elements LD described in the embodiments of FIGS. 1 and 2. For example, the first to third pixels PXL1, PXL2, and PXL3 may include light emitting elements LD that emit light of the same color, for example, a third color (or blue). A color conversion layer CCL including color conversion particles may be disposed on the first to third pixels PXL1, PXL2, and PXL3, so that a full-color image may be displayed.

The first color conversion layer CCL1 may include first color conversion particles that convert light of the third color emitted from the light emitting element LD into light of a first color. For example, the first color conversion layer CCL1 may include multiple first quantum dots QD1 dispersed in a matrix material such as a base resin.

In an embodiment, in case that the light-emitting element LD is a blue light-emitting element emitting blue light and the first pixel PXL1 is a red pixel, the first color conversion layer CCL1 may include a first quantum dot QD1 that converts light of the blue color emitted from the blue light-emitting element into the light of the red color. The first quantum dot QD1 may absorb blue light to shift a wavelength according to an energy transition, thereby emitting red light. In case that the first pixel PXL1 is a pixel of a different color, the first color conversion layer CCL1 may include a first quantum dot QD1 corresponding to the color of the first pixel PXL1.

The second color conversion layer CCL2 may include second color conversion particles that convert light of the third color emitted from the light emitting element LD into light of the second color. For example, the second color conversion layer CCL2 may include multiple second quantum dots QD2 dispersed in a matrix material such as a base resin.

In an embodiment, in case that the light-emitting element LD is a blue light-emitting element emitting blue light and the second pixel PXL2 is a green pixel, the second color conversion layer CCL2 may include a second quantum dot QD2 that converts the blue light emitted from the blue light-emitting element into the green light. The second quantum dot QD2 may absorb blue light to shift a wavelength according to an energy transition, thereby emitting green light. In case that the second pixel PXL2 is a pixel of a different color, the second color conversion layer CCL2 may include a second quantum dot QD2 corresponding to the color of the second pixel PXL2.

In an embodiment, the absorption coefficient of the first quantum dot QD1 and the second quantum dot QD2 may be increased by injecting blue light having a relatively short wavelength in the visible light range to the first quantum dot QD1 and the second quantum dot QD2. Accordingly, the light efficiency emitted from the first pixel PXL1 and the second pixel PXL2 may be improved, and excellent color reproducibility may be secured finally. The light emitting unit EMU of the first to third pixels PXL1, PXL2, and PXL3 may include the light emitting elements LD (e.g., blue light emitting elements) of the same color, thereby manufacturing efficiency of the display device may be increased.

The scattering layer LSL may be provided to efficiently use the third color (or blue) light emitted from the light emitting element LD. For example, in case that the light emitting element LD is a blue light emitting element that emits blue light and the third pixel PXL3 is a blue pixel, the scattering layer LSL may include at least one type of scattering body SCT to use efficiently the light emitted from the light emitting element LD. For example, the scattering body SCT of the scattering layer LSL may include at least one of barium sulfate (BaSO₄), calcium carbonate (CaCO₃), titanium oxide (TiO₂), silicon oxide (SiO₂), aluminum oxide (Al₂O₃), zirconium oxide (ZrO₂), and zinc oxide (ZnO). The scattering body SCT may be disposed in the third pixel PXL3, or may be selectively included in the first color conversion layer CCL1 or the second color conversion layer CCL2. According to embodiments, the scattering layer LSL made of a transparent polymer may be provided by omitting the scattering body SCT.

A first capping layer CPL1 may be disposed on the color conversion layer CCL. The first capping layer CPL1 may be provided over the first to third pixels PXL1, PXL2, and PXL3. The first capping layer CPL1 may cover the color conversion layer CCL. The first capping layer CPL1 may prevent impurities such as moisture or air from penetrating from the outside and damaging or contaminating the color conversion layer CCL.

The first capping layer CPL1 may be an inorganic layer and may be made of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), etc.

An optical layer OPL may be disposed on the first capping layer CPL1. The optical layer OPL may serve to improve light extraction efficiency by recycling light provided from the color conversion layer CCL through total reflection. To this end, the optical layer OPL may have a relatively low refractive index than a refractive index of the color conversion layer CCL. For example, the refractive index of the color conversion layer CCL may be in a range of about 1.6 to 2.0, and the refractive index of the optical layer OPL may be in a range of about 1.1 to 1.3.

A second capping layer CPL2 may be disposed on the optical layer OPL. The second capping layer CPL2 may be provided over the first to third pixels PXL1, PXL2, and PXL3. The second capping layer CPL2 may cover the optical layer OPL. The second capping layer CPL2 may prevent impurities such as moisture or air from penetrating from the outside and damaging or contaminating the optical layer OPL.

The second capping layer CPL2 may be an inorganic layer and may be made of silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), etc.

A planarization layer PLL may be disposed on the second capping layer CPL2. The planarization layer PLL may be provided over the first to third pixels PXL1, PXL2, and PXL3.

The planarization layer PLL may include an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not necessarily limited thereto, and the planarization layer PLL may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

A color filter layer CFL may be disposed on the planarization layer PLL. The color filter layer CFL may include color filters CF1, CF2, and CF3 corresponding to the color of each pixel PXL. A full-color image may be displayed by disposing color filters CF1, CF2, and CF3 corresponding to colors of the first to third pixels PXL1, PXL2, and PXL3 respectively.

The color filter layer CFL may include a first color filter CF1 that is disposed in the first pixel PXL1 and selectively transmits light emitted from the first pixel PXL1, a second color filter CF2 that is disposed in the second pixel PXL2 and selectively transmits light emitted from the second pixel PXL2, and a third color filter CF3 that is disposed in the third pixel PXL3 and selectively transmits light emitted from the third pixel PXL3.

In an embodiment, the first color filter CF1, the second color filter CF2, and the third color filter CF3 may be a red color filter, a green color filter, and a blue color filter, respectively, but the disclosure is not necessarily limited thereto. Hereinafter, the term “color filter CF” or “color filters CF” may refer to any color filter of the first color filter CF1, the second color filter CF2, and the third color filter CF3, or may refer to two or more types of color filters collectively.

The first color filter CF1 may overlap the first color conversion layer CCL1 in the third direction (Z-axis direction). The first color filter CF1 may include a color filter material that selectively transmits light of a first color (or red). For example, in case that the first pixel PXL1 is the red pixel, the first color filter CF1 may include a red color filter material.

The second color filter CF2 may overlap the second color conversion layer CCL2 in the third direction (Z-axis direction). The second color filter CF2 may include a color filter material that selectively transmits light of the second color (or green). For example, in case that the second pixel PXL2 is the green pixel, the second color filter CF2 may include a green color filter material.

The third color filter CF3 may overlap the scattering layer LSL in the third direction (Z-axis direction). The third color filter CF3 may include a color filter material that selectively transmits light of a third color (or blue). For example, in case that the third pixel PXL3 is the blue pixel, the third color filter CF3 may include a blue color filter material.

According to embodiments, a light blocking layer BM may be further disposed between the first to third color filters CF1, CF2, and CF3. As such, in case that the light blocking layer BM is formed between the first to third color filters CF1, CF2, and CF3, color mixing defects visible from the front surface or side surface of the display device may be prevented. The material of the light blocking layer BM is not particularly limited, and may include various light blocking materials. For example, the light blocking layer BM may be implemented by stacking the first to third color filters CF1, CF2, and CF3.

An overcoat layer OC may be disposed on the color filter layer CFL. The overcoat layer OC may be provided over the first to third pixels PXL1, PXL2, and PXL3. The overcoat layer OC may cover the lower member including the color filter layer CFL. The overcoat layer OC may prevent moisture or air from penetrating into the above-described lower member. The overcoat layer OC may protect the above-described lower member from foreign substances such as dust.

The overcoat layer OC may include an organic material such as an acrylic resin, an epoxy resin, a phenolic resin, a polyamide resin, a polyimide resin, a polyester resin, a polyphenylenesulfide resin, or benzocyclobutene (BCB). However, the disclosure is not necessarily limited thereto, and the overcoat layer OC may include various types of inorganic materials including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), or titanium oxide (TiOₓ).

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode and a second electrode spaced apart from each other; and
light emitting elements disposed between the first electrode and the second electrode, wherein
each of the light emitting elements includes:
a first semiconductor layer;
a second semiconductor layer disposed on the first semiconductor layer; and
an active layer disposed between the first semiconductor layer and the second semiconductor layer,
each of the light emitting elements emits light with a wavelength in a range of about 464 nm to about 468 nm at a current density in a range of about 0.5 A/cm² to about 100 A/cm², and
each of the light emitting elements has a maximum external quantum efficiency greater than or equal to about 15%.

2. The display device of claim 1, wherein a thickness of the active layer is in a range of about 1.0 nm to about 2.8 nm.

3. The display device of claim 1, wherein a mole fraction of indium in the active layer is in a range of about 0.17 to about 0.20.

4. The display device of claim 1, wherein a length of the light emitting elements is less than or equal to about 50 um.

5. The display device of claim 1, wherein
the first electrode overlaps the first semiconductor layer in a plan view, and
the second electrode overlaps the second semiconductor layer in a plan view.

6. The display device of claim 1, further comprising:
a first connection electrode and a second connection electrode disposed on the light emitting elements.

7. The display device of claim 6, wherein
the first connection electrode is electrically connected to the first semiconductor layer, and
the second connection electrode is electrically connected to the second semiconductor layer.

8. The display device of claim 6, wherein
the first connection electrode is electrically connected to the first electrode, and
the second connection electrode is electrically connected to the second electrode.

9. The display device of claim 1, further comprising:
a color conversion layer disposed on the light emitting elements.

10. The light emitting element of claim 9, wherein the color conversion layer includes a first color conversion layer, a second color conversion layer, and a scattering layer.

11. The display device of claim 10, wherein
the first color conversion layer includes a first quantum dot, and
the second color conversion layer includes a second quantum dot.

12. The display device of claim 10, wherein the scattering layer includes a scattering body.

13. The display device of claim 12, further comprising:
a color filter layer disposed on the color conversion layer.

14. The display device of claim 13, wherein the color filter layer includes a first color filter overlapping the first color conversion layer in a plan view, a second color filter overlapping the second color conversion layer in a plan view, and a third color filter overlapping the scattering layer in a plan view.

15. The display device of claim 14, further comprising:
a light blocking layer disposed between the first color filter, the second color filter, and the third color filter.

16. A light emitting element comprising:
a first semiconductor layer;
a second semiconductor layer disposed on the first semiconductor layer; and
an active layer disposed between the first semiconductor layer and the second semiconductor layer, wherein
the light emitting element emits light with a wavelength in a range of about 464 nm to about 468 nm at a current density in a range of about 0.5 A/cm² to about 100 A/cm², and
the light emitting element has a maximum external quantum efficiency greater than or equal to about 15%.

17. The light emitting element of claim 16, wherein a thickness of the active layer is in a range of about 1.0 nm to about 2.8 nm.

18. The light emitting element of claim 16, wherein a mole fraction of indium in the active layer is in a range of about 0.17 to about 0.20.

19. The light emitting element of claim 16, further comprising:
an electrode layer disposed on the first semiconductor layer.

20. The light emitting element of claim 16, further comprising:
an insulating film surrounding the first semiconductor layer, the active layer, and the second semiconductor layer.
